(19) United States
(12) Patent Application Publication
(10) Pub. No.: US 2009/0302916 A1
(43) Pub. Date: Dec. 10, 2009

(54) Low Power and Full Swing Pseudo CML Latched Logic-Gates

(76) Inventor: Sarabjeet Singh, Bangalore (IN)

Correspondence Address: IBM CORPORATION;ROCHESTER IP LAW DEPT. 917, 3605 HIGHWAY 52 NORTH, ROCHESTER, MN, 55901-7829, US

(21) Appl. No.: 12/133,602

(22) Filed: Jun. 5, 2008

(51) Int. Cl. H03K 3/00

(52) U.S. Cl. 327/218

(57) ABSTRACT

“Negative And” (NAND) logic gate metal oxide semiconductor field effect transistor (MOSFET) switch(es) incorporated in the first stage of a “pseudo” current mode logic (CML) latch to provide a low-resistance (or high-resistance) circuit path to the output depending on the input voltage. This/these switch(es) are also used to deactivate the first stage of the circuit during the second half of a timing clock cycle, so as to permit the first stage to be activated only during the first half of a clock cycle. “Cross-coupled” inverter(s) are also used in the second stage of the circuit to provide acceptable “rail-to-rail” output voltage differential “swing” using less current. In addition, the second stage also has MOSFET switch(es) which activate only during the second half of a timing clock cycle and are deactivated during the first half of a clock cycle, which requires use of less current and thus reduces power consumption.

### FIELD OF THE INVENTION

This invention relates generally to “current mode logic” (CML) integrated circuit memory latches.

### BACKGROUND OF THE INVENTION

Complimentary metal oxide semiconductor field effect transistor (CMOS) “current mode logic” (CML) circuits are widely used for memory latches in very large scale integration (VLSI) computer chip design because they provide high switching speeds. In this context, in modern conventional designs of high speed mixed signal products and pipelined microprocessors, clocked latched logic gates are among the basic elements.

In a simple circuit implementation of the pipeline microprocessor, for example, inputs are stored at a first clocked latch, processed by a first logic unit, stored again at a second clocked latch, processed by a second logic unit, and stored again at a third clocked latch, which generates outputs. The inputs and outputs can be static or dynamic signals or can be generated from CML Logic-Gates. In general, dynamic and CML implementations achieve faster speed with higher power consumption. However, problems have long been encountered in that CML Logic-Gates tend to consume a great deal of power and do not have full rail-to-rail swing. Accordingly, a compelling need has been recognized in connection with improving upon such shortcomings.

### SUMMARY OF THE INVENTION

Broadly contemplated herein, in accordance with at least one presently preferred embodiment of the present invention, is a combination of features of conventional CML Logic-Gates and also of CMOS Latches, in a manner to bring about lower power consumption and to provide full swing rail-to-rail output.

In summary, one aspect of the invention provides a high speed integrated circuit memory latched logic gate device comprising a first and second current mode logic transistor circuit arrangement, the latched logic gate device comprising: a switching arrangement acting to: selectively switch the first circuit on and off in consonance with a clock cycle; selectively switch the second circuit on and off in consonance with a clock cycle; and interrelate the switching on and off of the first and second circuits based on the clock cycle; and an arrangement in the second circuit acting to retain the output signal level.

Another aspect of the invention provides a computerized system using a high speed integrated circuit memory latched logic gate device comprising a first and second current mode logic transistor circuit arrangement, the latched logic gate device comprising: a switching arrangement acting to: selectively switch the first circuit on and off in consonance with a clock cycle; selectively switch the second circuit on and off in consonance with a clock cycle; and interrelate the switching on and off of the first and second circuits based on the clock cycle; and an arrangement in the second circuit acting to retain the output signal level.

Furthermore, an additional aspect of the invention provides a method of using a high speed integrated circuit memory latched logic gate device comprising a first and second current mode logic transistor circuit arrangement in a computerized system, the method comprising the steps of: selectively switching the first circuit on and off in consonance with a clock cycle; selectively switching the second circuit on and off in consonance with a clock cycle; interrelating the switching on and off of the first and second circuits based on the clock cycle; employing an arrangement in the second circuit acting to retain the output signal level.

For a better understanding of the present invention, together with other and further features and advantages thereof, reference is made to the following description, taken in conjunction with the accompanying drawings, and the scope of the invention will be pointed out in the appended claims.

### BRIEF DESCRIPTION OF THE DRAWINGS

FIG. 1 illustrates a conventional CMOS CML latched NAND gate design.

FIG. 2 illustrates a CML latched NAND gate design in accordance with an embodiment of the present invention.

FIG. 3 illustrates waveforms comparing the performance of prior art and inventive (“conventional” and “new”) CML latched NAND gates.

### DETAILED DESCRIPTION OF THE PREFERRED EMBODIMENTS

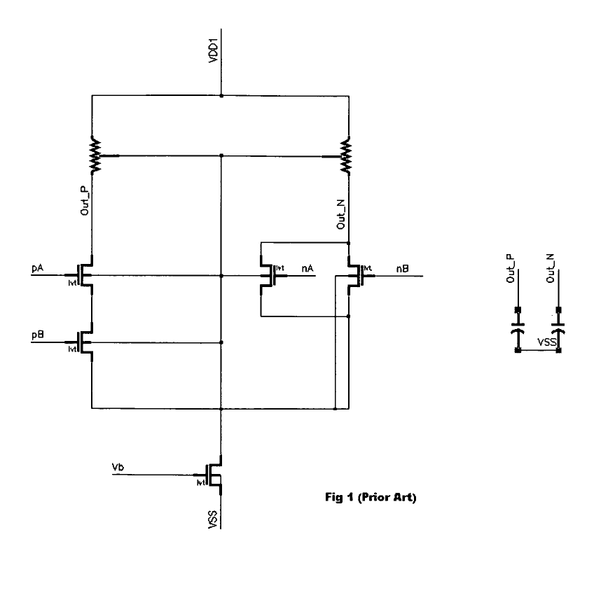

It will be readily understood that the components of the present invention, as generally described and illustrated in the Figures herein, may be arranged and designed in a wide variety of different configurations. Thus, the following more detailed description of the embodiments of the apparatus, system, and method of the present invention, as represented in FIGS. 1-3, is not intended to limit the scope of the invention, as claimed, but is merely representative of selected embodiments of the invention.

Reference throughout this specification to “one embodiment” or “an embodiment” (or the like) means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

Furthermore, the described features, structures, or characteristics may be combined in any suitable manner in one or more embodiments. In the following description, numerous specific details are provided, such as examples of hardware modules, hardware circuits, hardware chips, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

The illustrated embodiments of the invention will be best understood by reference to the drawings, wherein like parts are designated by like numerals or other labels throughout. The following description is intended only by way of example, and simply illustrates certain selected embodiments of devices, systems, and processes that are consistent with the invention as claimed herein.

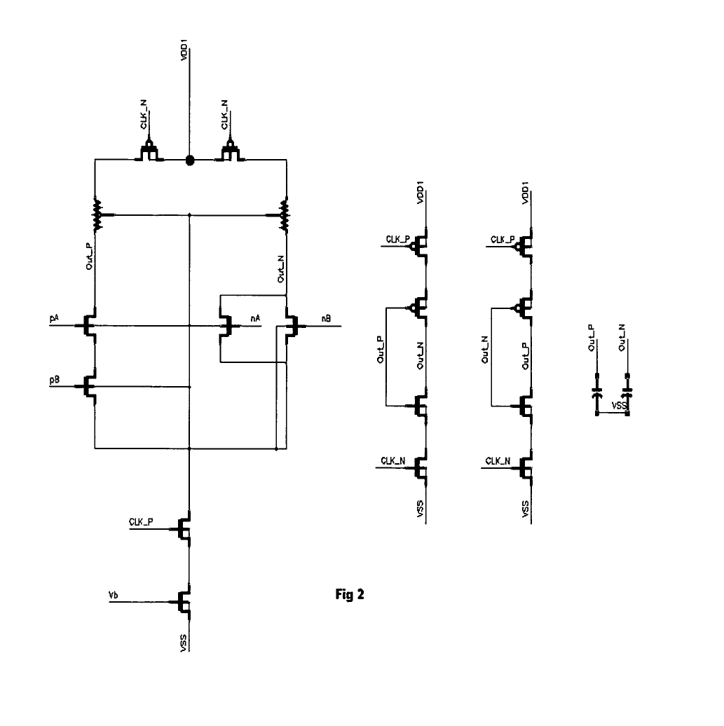

FIG. 1 illustrates a conventional CMOS CML latched NAND gate design using a three-layer “staggered” transistor circuit configuration involving a “current source” transistor along with “switch” transistor(s) and a “differential transistor pair” plus a resistive output load. As mentioned above, there is broadly contemplated herein, in accordance with at least one presently preferred embodiment of the present invention, a combination of features of conventional CML Logic-Gates and also of CMOS Latches, in a manner to bring about lower power consumption and to provide full swing rail-to-rail output. Preferably, this may be accomplished by incorporating MOS switches in first and second stage of CML Logic-Gates, as can be appreciated from the circuit design of FIG. 2.

Preferably, as shown in FIG. 2, a pair of MOSFET switches are used to switch-off the first stage during the second half of a clock cycle (the hold phase), while switching-on the first stage solely during first half of a clock cycle (the evaluation phase). On the other hand, as also can be appreciated from FIG. 2, the second stage preferably employs cross-coupled inverters for achieving rail-to-rail swing using much less current. At the same time, the second stage also preferably includes MOSFET switches which, in similar fashion to the first stage, selectively switch on and off relative to the clock cycle. In this case, however, the MOSFET switches switch-on only during second half of clock cycle (hold phase) and are switched-off during first half of clock cycle (evaluation phase). Here, as well, power consumption is greatly reduced via using minimal current during the second half of the clock cycle.

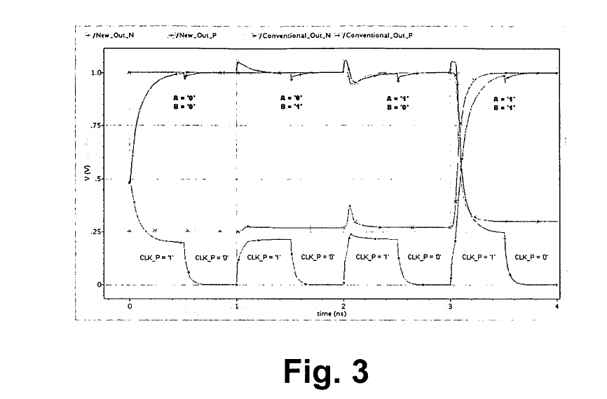

FIG. 3 shows waveforms with measurements taken at “Out_P” and “Out_N” in the circuit arrangement of FIG. 2. Also shown are values of 0 and 1 apportioned to the Logic-Gates (here, NAND) in question. The waveforms in FIG. 3 convey that the prior art (“conventional”) and inventive (“new”) CML circuits present significantly different current measurements despite the same current source transistor being used for both cases, while full rail-to-rail output power swing is indeed achieved in the inventive arrangement. The conventional arrangement, in particular, utilizes an average current of 4.8 mA, while the inventive arrangement utilizes a much lower average current of 2.3 mA. Thus, the inventive arrangement provides a savings of approximately 52% in average current usage, implying greatly reduced power requirements. Current savings in both halves of each clock cycle can be seen from the waveforms of FIG. 3.

Though specific reference has been made hereinabove to NAND gates, it should be understood that this has been provided merely as an illustrative and non-restrictive example; the inventive modifications discussed hereinabove can of course also be applied to a very wide variety of other types of Latched Logic-Gates, such as: AND, NOR/OR, NOT/Buffer, XOR, etc.

It is to be understood that the present invention, in accordance with at least one presently preferred embodiment, includes elements that may be implemented on at least one general-purpose computer. These may also be implemented on at least one Integrated Circuit or part of at least one Integrated Circuit. Thus, it is to be understood that the invention may be implemented in hardware, software, or a combination of both.

If not otherwise stated herein, it is to be assumed that all patents, patent applications, patent publications and other publications (including web-based publications) mentioned and cited herein are hereby fully incorporated by reference herein as if set forth in their entirety herein.

Although illustrative embodiments of the present invention have been described herein with reference to the accompanying drawings, it is to be understood that the invention is not limited to those precise embodiments, and that various other changes and modifications may be affected therein by one skilled in the art without departing from the scope or spirit of the invention.

What is claimed is:

1. A high speed integrated circuit memory latched logic gate device comprising a first and second current mode logic transistor circuit arrangement, said latched logic gate device comprising:
a switching arrangement acting to:
selectively switch the first circuit on and off in consonance with a clock cycle;
selectively switch the second circuit on and off in consonance with a clock cycle; and
interrelate the switching on and off of the first and second circuits based on the clock cycle; and
an arrangement in the second circuit acting to retain the output signal level.

2. The latched logic gate device according to claim 1, wherein said switching arrangement comprises a MOSFET switching arrangement.

3. The latched logic gate device according to claim 2, wherein said MOSFET switching arrangement comprises a pair of MOSFET switches disposed in the first circuit.

4. The latched logic gate device according to claim 2, wherein said MOSFET switching arrangement comprises a pair of MOSFET switches disposed in the second circuit.

5. The latched logic gate device according to claim 1, wherein said arrangement retaining the output signal level comprises a cross-coupled inverter arrangement.

6. The latched logic gate device according to claim 5, wherein said cross-coupled inverter arrangement comprises a pair of cross-coupled inverters disposed in the second circuit.

7. The latched logic gate device according to claim 1, wherein said switching arrangement acts to
switch the first circuit on and the second circuit off during a first half of a clock cycle; and
switch the second circuit on and the first circuit off during a second half of a clock cycle.

8. A computerized system using a high speed integrated circuit memory latched logic gate device comprising a first and second current mode logic transistor circuit arrangement, said latched logic gate device comprising:
a switching arrangement acting to:
selectively switch the first circuit on and off in consonance with a clock cycle;
selectively switch the second circuit on and off in consonance with a clock cycle; and
interrelate the switching on and off of the first and second circuits based on the clock cycle; and
an arrangement in the second circuit acting to retain the output signal level.

9. The system according to claim 8, wherein said switching arrangement comprises a MOSFET switching arrangement.

10. The system according to claim 9, wherein said MOSFET switching arrangement comprises a pair of MOSFET switches disposed in the first circuit.

11. The system according to claim 9, wherein said MOSFET switching arrangement comprises a pair of MOSFET switches disposed in the second circuit.

12. The system according to claim 8, wherein said arrangement retaining the output signal level comprises a cross-coupled inverter arrangement.

13. The system according to claim 12, wherein said cross-coupled inverter arrangement comprises a pair of cross-coupled inverters disposed in the second circuit.

14. The system according to claim 8, wherein said switching arrangement acts to
switch the first circuit on and the second circuit off during a first half of a clock cycle; and
switch the second circuit on and the first circuit off during a second half of a clock cycle.

15. A method of using a high speed integrated circuit memory latched logic gate device comprising a first and second current mode logic transistor circuit arrangement in a computerized system, the method comprising the steps of:
selectively switching the first circuit on and off in consonance with a clock cycle;
selectively switching the second circuit on and off in consonance with a clock cycle;
interrelating the switching on and off of the first and second circuits based on the clock cycle; and
employing an arrangement in the second circuit acting to retain the output signal level.

16. The method according to claim 15, wherein said employing comprises employing a cross-coupled inverter arrangement.

17. The method according to claim 15, wherein:
said switching of the first circuit comprises switching the first circuit on during a first half of a clock cycle and off during a second half of a clock cycle; and
said switching of the second circuit comprises switching the second circuit off during a first half of a clock cycle and on during a second half of a clock cycle.
